(19) United States
(12) Patent Application Publication
(10) Pub. No.: US 2019/0333425 A1
(43) Pub. Date: Oct. 31, 2019

(54) FLEXIBLE DISPLAY DEVICE

(71) Applicant: Sharp Kabushiki Kaisha, Sakai City, Osaka (JP)

(72) Inventors: Yuki YASUDA, Sakai City (JP); Tetsunori TANAKA, Sakai City (JP)

(21) Appl. No.: 16/468,330

(22) PCT Filed: Aug. 2, 2017
(86) PCT No.: PCT/JP2017/028079

§ 371 Date: Jun. 11, 2019

(51) Int. Cl. G09F 9/30; B32B 27/34; H01L 51/50; H01L 51/00; G02F 1/1333; H01L 27/12

(52) U.S. Cl. CPC G09F 9/301; B32B 27/34; H01L 51/5012; H01L 27/1218; H01L 51/003; G02F 1/133305; H01L 51/0097

(57) ABSTRACT

A step of forming a base layer on a surface on one side of a glass substrate includes a step of forming a first polyimide resin layer and a step of forming a second polyimide resin layer. The step of forming the first polyimide resin layer includes applying a first polyimide resin material while being spread in a first direction. The step of forming the second polyimide resin layer includes applying a second polyimide resin material while being spread in a second direction being a direction opposite to the first direction.

### TECHNICAL FIELD

The disclosure relates to a flexible display device and a method for manufacturing a flexible display device.

### BACKGROUND ART

In recent years, various flat panel displays are being developed. Particularly, Electro Luminescence (EL) display devices such as organic EL display devices including Organic Light Emitting Diodes (OLEDs) and inorganic EL display devices including inorganic light emitting diodes are receiving great attention because higher picture quality and low power consumption can be achieved.

Then, there is a high demand for display devices that do not have to include a backlight, such as the EL display devices and display devices including reflection liquid crystal display elements, to be flexible display devices so as to be freely bendable.

To achieve a flexible display device (flexible display device) having a high degree of reliability, the following method is generally used. In the method, a step of forming an active element (for example, a TFT element) being a high temperature step included as an essential step in steps of manufacturing a flexible display device and the like are performed on, for example, a glass substrate being a non-flexible substrate having high heat resistance, this glass substrate is then peeled, and flexibility is secured.

PTLs 1 to 4 describe that two resin layers made of a polyimide resin and the like are layered on a non-flexible substrate having high heat resistance, and a lower resin layer including the non-flexible substrate is peeled from an upper resin layer without irradiation of laser light after the above-described high temperature step.

### CITATION LIST

### Patent Literature

PTL 1: JP 2015-530283 A (published Oct. 15, 2015)

PTL 2: WO 2014/050933 (published Apr. 3, 2014)

PTL 3: JP 2016-120630 A (published Jul. 7, 2016)

PTL 4: JP 2016-120629 A (published Jul. 7, 2016)

### SUMMARY

### Technical Problem

However, while the methods described in PTLs 1 to 4 have an advantage in that there is no need for irradiation of laser light, a large amount of unnecessary resin layers are formed on the peeled non-flexible substrate because layers between the resin layer and the resin layer made of a polyimide resin and the like are peeled.

Therefore, the methods described in PTLs 1 to 4 are not preferable methods in terms of efficient use of a polyimide material forming a resin layer and in terms of an eco-friendly step.

Thus, usage of a method as illustrated in FIGS. 5A to 5C below is conceivable.

FIGS. 5A to 5C are diagrams illustrating a laser lift off step (also referred to as an LLO step) needed for manufacturing a flexible organic EL display device having a high degree of reliability.

As illustrated in FIG. 5A, a PI layer 102 (base layer) made of, for example, a polyimide resin is first layered on a surface 101a on one side of a large glass substrate 101 (non-flexible substrate) (a first step), a moisture-proof layer 103 is layered on the PI layer 102, and a TFT array layer 104 formed of a thin film transistor element (TFT element) and an insulating film is formed on the moisture-proof layer 103. A first electrode (not illustrated) corresponding to an individual pixel is patterned and formed on the TFT array layer 104 by using a metal film in the same layer, and a terminal portion (not illustrated) is also formed on the TFT array layer 104. Then, any of a red light-emitting organic EL element 105R, a green light-emitting organic EL element 105G, and a blue light-emitting organic EL element 105B is formed as a display element on the first electrode (a second step), and a sealing film 106 is formed to cover the red light-emitting organic EL element 105R, the green light-emitting organic EL element 105G, and the blue light-emitting organic EL element 105B.

Note that, each of the red light-emitting organic EL element 105R, the green light-emitting organic EL element 105G, and the blue light-emitting organic EL element 105B is, for example, a layered body of a hole injection layer, a hole transport layer, a light-emitting layer in each color, an electron transport layer, an electron injection layer, and a second electrode, which are not illustrated.

As illustrated, a layered body of the moisture-proof layer 103, the TFT array layer 104, the red light-emitting organic EL element 105R, the green light-emitting organic EL element 105G, the blue light-emitting organic EL element 105B, and the sealing layer 106 is a layered body 107.

Subsequently, ablation occurs at an interface between the PI layer 102 (base layer) and the glass substrate 101 by irradiation with laser light from the glass substrate 101 side, and, as illustrated in FIG. 5B, the glass substrate 101 is peeled from the PI layer 102 (base layer) (a third step).

Next, as illustrated in FIG. 5C, a back film 111 as a flexible substrate is bonded to the PI layer 102 (base layer) with an adhesive layer (not illustrated) provided on a surface 111a on one side of the back film 111 between the back film 111 and the PI layer 102, and a flexible organic EL display device is then completed (a fourth step).

As described above, a more efficient use of a polyimide material forming a PI layer (base layer) and a more eco-friendly step can be achieved by using the LLO step than those in the methods described in PTLs 1 to 4.

However, in the method for manufacturing a flexible organic EL display device illustrated in FIGS. 5A to 5C, the following problem occurs when the PI layer 110 (base layer) made of a polyimide resin is applied to a large glass substrate 101′ (non-flexible substrate) by using a slit coater in order to improve productivity of the flexible organic EL display device.

FIG. 6 is a diagram illustrating a problem occurring when the PI layer 110 made of a polyimide resin is applied to the large glass substrate 101′ by using the slit coater.

As illustrated, the PI layer 110 (base layer) formed on the glass substrate 101′ by using the slit coater has a thicker film thickness formed at an portion A in the diagram near a start position of application by the slit coater than at the other portion, and has a thinner film thickness formed at a portion B in the diagram near a stop position of the application by the slit coater than at the other portion.

In this way, with great in-plane variations in film thickness of the PI layer 110 (base layer), when an amount of irradiation with laser light in the above-described LLO step is set with reference to an average film thickness, the portion as the portion A in the diagram having a film thickness thicker than that of the other portion lacks in the amount of irradiation with laser light and becomes a portion in which a peeling trouble occurs. On the other hand, the portion as the portion B in the diagram having a film thickness thinner than that of the other portion has no rigidity of a film itself, and becomes a portion in which a peeling trouble occurs regardless of the amount of irradiation with laser light.

Furthermore, when the PI layer 110 (base layer) being a foundation film has a portion having a film thickness thicker than that of the other portion or has a portion having a film thickness thinner than that of the other portion, a problem also occurs where it is difficult to secure a distance (gap) between a vapor deposition mask and a non-flexible substrate (for example, a glass substrate) at a fixed distance during formation of a vapor deposition film by bringing the vapor deposition mask into contact with a side of a surface of the non-flexible substrate on which the PI layer 110 (base layer) is formed in steps of forming a display element and a step of forming a sealing film being subsequent steps.

The disclosure has been made in view of the above-described problem, and an object thereof is to provide a method for manufacturing a flexible display device that can secure a distance (gap) between a vapor deposition mask used in subsequent step and a non-flexible substrate at a fixed distance, and also reduces generation of a large amount of unnecessary resin layers and a peeling trouble between a resin layer and a substrate, and to provide a flexible display device having high productivity.

### Solution to Problem

To solve the above-described problem, a method for manufacturing a flexible display device of the disclosure is a method for manufacturing a flexible display device including: a first step of forming a base layer on a surface on one side of a non-flexible substrate; a second step of forming a display element on the base layer; a third step of performing irradiation with laser light from a side of the non-flexible substrate to peel the non-flexible substrate from the base layer; and a fourth step of bonding a flexible substrate to a surface of the base layer from which the non-flexible substrate is peeled, where a step of forming the base layer in the first step includes a step of forming a first resin layer and a step of forming a second resin layer, and the step of forming the first resin layer includes applying a first resin material while being spread in a first direction and, the step of forming the second resin layer includes applying a second resin material while being spread in a second direction being a direction opposite to the first direction.

According to the above-described method, the step of forming the first resin layer includes the first resin material while being spread in the first direction, and the step of forming the second resin layer includes applying the second resin material while being spread in the second direction being the direction opposite to the first direction. Thus, a film thickness of the base layer is leveled by using generated variations in film thickness in each of the step of forming the first resin layer and the step of forming the second resin layer.

Therefore, setting the amount of irradiation with laser light to the base layer is easy, and a peeling trouble occurring when the non-flexible substrate is peeled from the base layer can be suppressed.

According to the above-described method, the non-flexible substrate is peeled from the base layer. Thus, a large amount of unnecessary resin layers is not left on the peeled non-flexible substrate unlike the method described in the related art (PTLs 1 to 4 described above).

According to the above-described method, a film thickness of the base layer is leveled. Thus, a distance (gap) between a vapor deposition mask and the non-flexible substrate can be secured at a fixed distance.

According to the above-described method, the step of forming the base layer includes the step of forming the first resin layer and the step of forming the second resin layer. Thus, even when a foreign matter is mixed during the formation of the first resin layer, the second resin layer can bury this foreign matter.

Furthermore, according to the above-described method, even when each of the first resin layer and the second resin layer constituting the base layer can be formed only as a thin film, the base layer is formed of the first resin layer and the second resin layer, and can thus have a relatively thick film.

To solve the above-described problem, a flexible display device of the disclosure is a flexible display device including: a flexible substrate; a base layer provided on a surface on one side of the flexible substrate; and a display element provided on the base layer, where the base layer is formed of a first polyimide resin layer and a second polyimide resin layer contacting the first polyimide resin layer on the first polyimide resin layer.

According to the above-described configuration, the base layer is formed of the first polyimide resin layer and the second polyimide resin layer contacting the first polyimide resin layer on the first polyimide resin layer.

Therefore, setting the amount of irradiation with laser light to the base layer is easy, and a peeling trouble occurring when the non-flexible substrate is peeled from the base layer can be suppressed. Thus, the flexible display device having high productivity can be achieved.

To solve the above-described problem, a flexible display device of the disclosure is a flexible display device including: a flexible substrate; a base layer provided on a surface on one side of the flexible substrate; and a display element provided on the base layer, where the base layer is formed of a first polyimide resin layer, an inorganic film contacting the first polyimide resin layer on the first polyimide resin layer, and a second polyimide resin layer contacting the inorganic film on the inorganic film.

According to the above-described configuration, the base layer is formed of the first polyimide resin layer, the inorganic film contacting the first polyimide resin layer on the first polyimide resin layer, and the second polyimide resin layer contacting the inorganic film on the inorganic film. Thus, setting the amount of irradiation with laser light to the base layer is easy, and a peeling trouble occurring when the non-flexible substrate is peeled from the base layer can be suppressed. Therefore, the flexible display device having high productivity can be achieved.

According to the above-described configuration, the base layer is provided with the inorganic film. Thus, the flexible display device having high moisture resistance and improved adhesion between the first polyimide resin layer and the second polyimide resin layer can be achieved.

### Advantageous Effects of Disclosure

One aspect of the disclosure can provide a method for manufacturing a flexible display device that can secure a distance (gap) between a vapor deposition mask used in subsequent steps and a non-flexible substrate at a fixed distance, and also reduces generation of a large amount of unnecessary resin layers and a peeling trouble between a resin layer and a substrate, and provide a flexible display device having high productivity.

### BRIEF DESCRIPTION OF DRAWINGS

FIGS. 1A and 1B are diagrams illustrating a method for forming a base layer formed of a first polyimide resin layer and a second polyimide resin layer on a glass substrate.

FIG. 2 is a diagram when plasma treatment is performed on at least a surface of the first polyimide resin layer illustrated in FIGS. 1A and 1B.

FIGS. 3A to 3C are diagrams illustrating a method for forming a base layer formed of a first polyimide resin layer, a silicon oxide film, and a second polyimide resin layer on a glass substrate.

FIGS. 4A to 4D are diagrams illustrating a step of peeling a glass substrate from a base layer.

FIGS. 5A to 5C are diagrams illustrating a laser lift off step needed for manufacturing a flexible organic EL display device having a high degree of reliability.

FIG. 6 is a diagram illustrating a problem occurring when a PI layer made of a polyimide resin is applied to a large glass substrate by using a slit coater.

### DESCRIPTION OF EMBODIMENTS

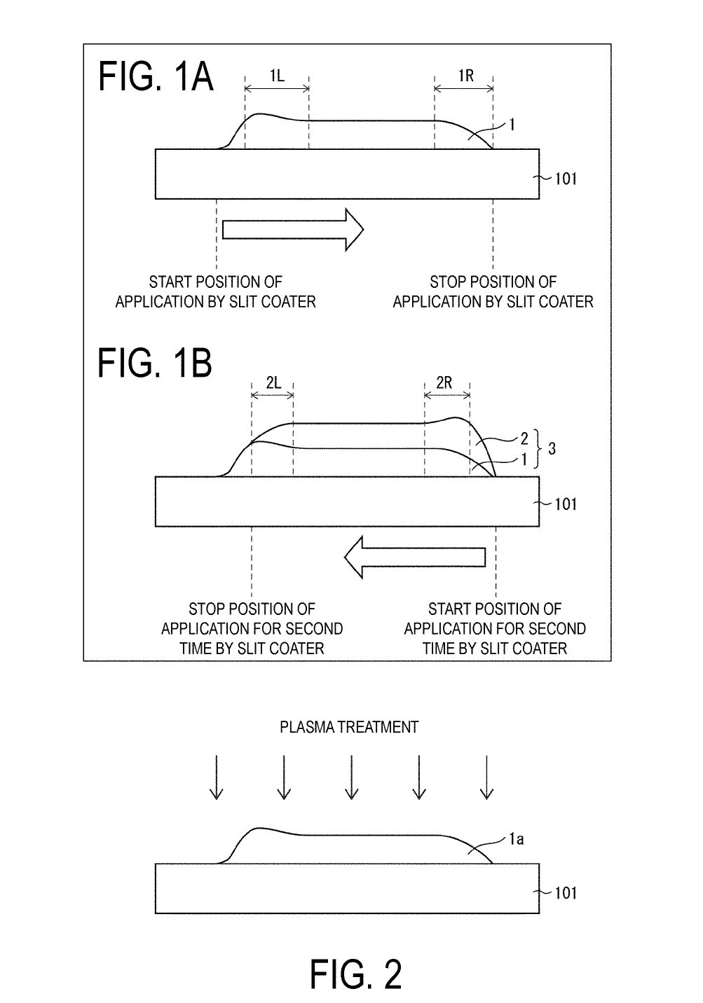

The following is a description regarding embodiments of the disclosure, with reference to FIGS. 1A to 4D. Hereinafter, for convenience of descriptions, a configuration having the same functions as those of a configuration described in a specific embodiment are denoted by the same reference numerals, and its descriptions may be omitted.

Note that, a flexible organic EL display device including a red light-emitting organic EL element 105R, a green light-emitting organic EL element 105G, and a blue light-emitting organic EL element 105B as display elements is described as one example in each of the embodiments below, which is not limited thereto. A flexible display device provided with, for example, a reflection liquid crystal display element as the display element may be used.

### First Embodiment

A first embodiment of the disclosure will be described with reference to FIGS. 1A, 1B, and 2.

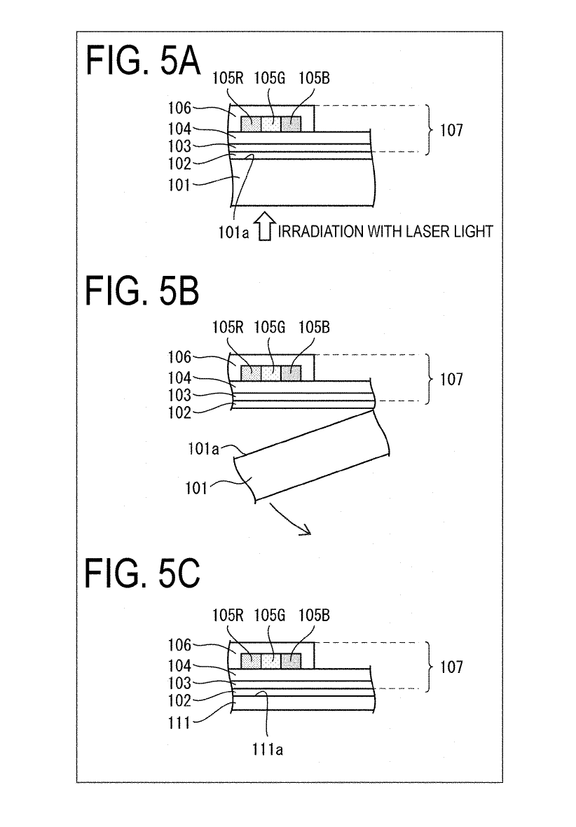

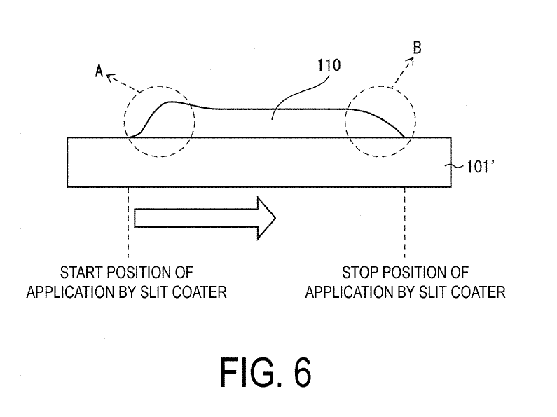

The present embodiment is different from the method for manufacturing a flexible organic EL display device with reference to FIGS. 5A and 6 in the method for forming the PI layers 102 and 110 made of a polyimide resin and respectively formed on the surface on one side of the large glass substrates 101 and 101′ (non-flexible substrates) and the configuration of the film thereof. The other is as described with reference to FIGS. 5A and 6.

FIGS. 1A and 1B are diagrams illustrating a method for forming a base layer 3 formed of a first polyimide resin layer 1 and a second polyimide resin layer 2 on a large glass substrate 101.

The PI layer 102 in FIG. 5A as a base layer and the PI layer 110 in FIG. 6 as a base layer both have a single layer formed as a base layer. In contrast, as illustrated in FIGS. 1A and 1B, the base layer 3 is formed of the first polyimide resin layer 1 and the second polyimide resin layer 2, and a step of forming the base layer 3 includes a step of forming the first polyimide resin layer 1 (a step of forming a first resin layer) and a step of forming the second polyimide resin layer 2 (a step of forming a second resin layer).

In the step of forming the first polyimide resin layer 1 on the large glass substrate 101 as illustrated in FIG. 1A (the step of forming a first resin layer), a slit coater, which is not illustrated, is used.

The slit coater moves in a right direction (first direction) in the diagram from a start position of application by the slit coater in the diagram to a stop position of the application by the slit coater, and can thus apply a first polyimide resin material that forms the first polyimide resin layer 1 while spreading the first polyimide resin material in the right direction in the diagram.

As illustrated in FIG. 1A, in the first polyimide resin layer 1 formed on the glass substrate 101 by using the slit coater, a portion 1L (first portion) having a film thickness thicker than that of the other portion in the first polyimide resin layer 1 is formed near the start position of the application by the slit coater, and a portion 1R (third portion) having a film thickness thinner than that of the other portion in the first polyimide resin layer 1 is formed near the stop position of the application by the slit coater.

Note that, the slit coater is long in a depth direction in the diagram, and thus the portion 1L having a film thickness thicker than that of the other portion in the first polyimide resin layer 1 and the portion 1R having a film thickness thinner than that of the other portion in the first polyimide resin layer 1 are formed linearly in the depth direction in the diagram on the glass substrate 101.

A film thickness of a portion having the thickest film thickness of the portion 1L having a film thickness thicker than that of the other portion in the first polyimide resin layer 1 is about 1.3 to 2.0 times an average film thickness of the entire first polyimide resin layer 1. Variations in film thickness of the first polyimide resin layer 1 are relatively great in a plane of the glass substrate 101.

Subsequently, as illustrated in FIG. 1B, the slit coater, which is not illustrated, is also used in the step of forming the second polyimide resin layer 2 (the step of forming the second resin layer) in order to reduce variations in film thickness of the first polyimide resin layer 1 in the plane of the glass substrate 101 described above.

The slit coater moves in a left direction (second direction) in the diagram from a start position of application for a second time by the slit coater in the diagram to a stop position of the application for the second time by the slit coater, and can thus apply a second polyimide resin material that forms the second polyimide resin layer 2 while spreading the second polyimide resin material in the left direction in the diagram.

As illustrated in FIG. 1B, in the second polyimide resin layer 2 formed by using the slit coater, a portion 2R (fourth portion) having a film thickness thicker than that of the other portion in the second polyimide resin layer 2 is formed near the start position of the application for the second time by the slit coater, and a portion 2L (second portion) having a film thickness thinner than that of the other portion in the second polyimide resin layer 2 is formed near the stop position of the application for the second time by the slit coater, similarly to the first polyimide resin layer 1.

Note that, the slit coater is long in a depth direction in the diagram, and thus the portion 2R having a film thickness thicker than that of the other portion in the second polyimide resin layer 2 and the portion 2L having a film thickness thinner than that of the other portion in the second polyimide resin layer 2 are formed linearly in the depth direction in the diagram on the glass substrate 101.

As illustrated in FIG. 1B, the first polyimide resin layer 1 and the second polyimide resin layer 2 are provided to contact each other, the portion 1L (first portion) having a film thickness thicker than that of the other portion in the first polyimide resin layer 1 overlaps the portion 2L (second portion) having a film thickness thinner than that of the other portion in the second polyimide resin layer 2 in a plan view, and the portion 1R (third portion) having a film thickness thinner than that of the other portion in the first polyimide resin layer 1 overlaps the portion 2R (fourth portion) having a film thickness thicker than that of the other portion in the second polyimide resin layer 2 in the plan view.

As described above, in the base layer 3 formed of the first polyimide resin layer 1 and the second polyimide resin layer 2, a film thickness of the base layer 3 is leveled by using generated variations in film thickness in each of the step of forming the first polyimide resin layer 1 and the step of forming the second polyimide resin layer 2.

Therefore, setting the amount of irradiation with laser light to the base layer 3 is easy, and a peeling trouble occurring when the glass substrate 101 is peeled from the base layer 3 can be suppressed.

The glass substrate 101 is peeled from the base layer 3, and thus the first polyimide resin layer 1 and the second polyimide resin layer 2 are left on the flexible organic EL display device side in the end, and thus a large amount of unnecessary resin layers is not generated.

Further, the base layer 3 formed of the first polyimide resin layer 1 and the second polyimide resin layer 2 is used in the flexible organic EL display device in the present embodiment, and thus sufficient moisture resistance can be secured.

In the present embodiment, in order to level a film thickness of the base layer 3 with a higher degree of precision, the same material is used as the first polyimide resin material forming the first polyimide resin layer 1 and the second polyimide resin material forming the second polyimide resin layer 2, and a scan speed of the slit coater at the application for the first time is also the same as a scan speed of the slit coater at the application for the second time. However, as long as variations in film thickness of the first polyimide resin layer 1 in the plane of the glass substrate 101 can be reduced, the same material may not be used, and the scan speed of the slit coater at the application for the first time may be different from the scan speed of the slit coater at the application for the second time.

In the present embodiment, the case where the base layer 3 is formed of the first polyimide resin layer 1 and the second polyimide resin layer 2 is described as one example, which is not limited thereto. As long as ablation can be caused at an interface between the base layer 3 and the glass substrate 101 by irradiation with laser light from the glass substrate 101 side and the glass substrate 101 can be peeled from the base layer 3, a resin material other than a polyimide resin material may be used.

In the present embodiment, the case where the first polyimide resin layer 1 and the second polyimide resin layer 2 are applied by using the slit coater is described as one example. However, a coating device is not particularly limited as long as a coating device is a type that applies a coating material while spreading the coating material in one direction, and also generates variations in film thickness of an applied film in a start position of the application and a stop position of the application.

In the present embodiment, heat treatment is performed on the first polyimide resin layer 1 after the step of forming the first polyimide resin layer 1 illustrated in FIG. 1A and before the step of forming the second polyimide resin layer 2 illustrated in FIG. 1B, which is not limited thereto. Heat treatment may be performed on the first polyimide resin layer 1 and the second polyimide resin layer 2 after the formation of the first polyimide resin layer 1 and the second polyimide resin layer 2.

By performing heat treatment (post-bake) on the first polyimide resin layer 1 after the step of forming the first polyimide resin layer 1 and before the step of forming the second polyimide resin layer 2, a shape of the first polyimide resin layer 1 can be almost fixed before the step of forming the second polyimide resin layer 2.

The second polyimide resin layer 2 can be formed while a shape of the first polyimide resin layer 1 being almost fixed in such a manner is taken into consideration, and thus a film thickness of the base layer 3 can be leveled with a higher degree of precision.

Note that, when adhesion between the first polyimide resin layer 1 and the second polyimide resin layer 2 is taken into consideration, hydrophilic treatment is preferably performed on at least a surface of the first polyimide resin layer 1.

FIG. 2 is a diagram when plasma treatment being one example of hydrophilic treatment is performed on at least a surface 1a of the first polyimide resin layer 1 formed on the glass substrate 101.

By performing plasma treatment on at least the surface 1a of the first polyimide resin layer 1 formed on the glass substrate 101 as illustrated, adhesion between the first polyimide resin layer 1 and the second polyimide resin layer 2 can be improved.

In the present embodiment, plasma treatment is described as one example of hydrophilic treatment on at least the surface of the first polyimide resin layer 1, which is not limited thereto. Physical or chemical hydrophilic treatment can be performed.

The step of performing hydrophilic treatment on at least the surface of the first polyimide resin layer 1 is preferably performed after the step of performing heat treatment (post-bake) on the first polyimide resin layer 1 and before the step of forming the second polyimide resin layer 2.

The reason is that an effect of hydrophilic treatment is conceivably reduced by heat treatment when hydrophilic treatment is performed on at least the surface of the first polyimide resin layer 1 before the step of performing heat treatment (post-bake) on the first polyimide resin layer 1.

Note that, the slit coater in the present embodiment is a coating device including a long nozzle that discharges a coating liquid in a direction orthogonal to a movement direction of the slit coater, and is a device generally used for forming a coating film on a large mother board with high productivity.

### Second Embodiment

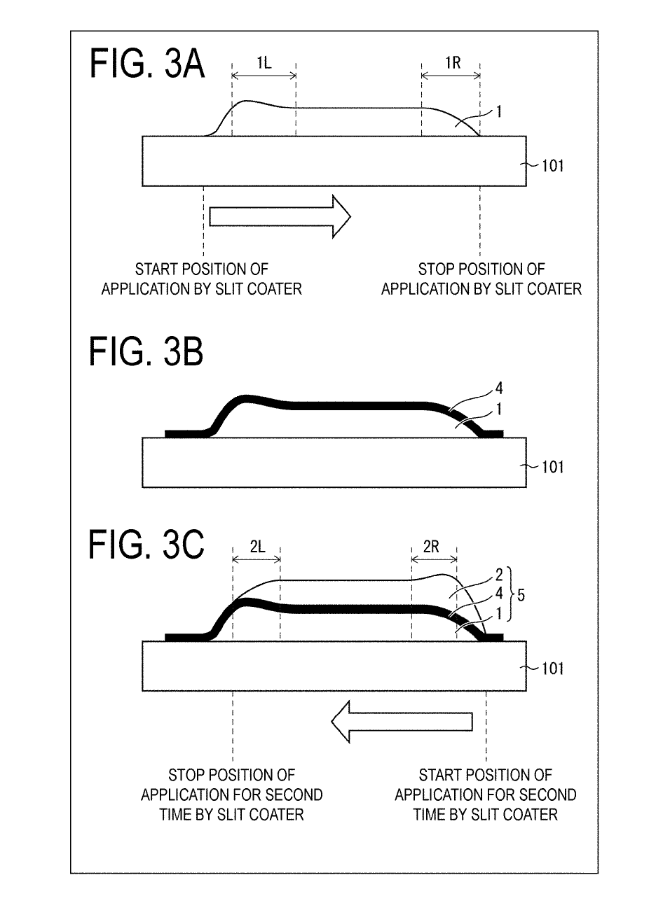

Next, a second embodiment of the disclosure will be described below with reference to FIGS. 3A to 3C. The present embodiment is different from the first embodiment in that a base layer 5 is formed of a first polyimide resin layer 1, a silicon oxide film 4 provided so as to contact the first polyimide resin layer 1 on the first polyimide resin layer 1, and a second polyimide resin layer 2 provided so as to contact the silicon oxide film 4 on the silicon oxide film 4. The other is as described in the first embodiment. For convenience of descriptions, members having the same functions as those of the members illustrated in the diagrams in the first embodiment are denoted by the same reference numerals, and descriptions thereof will be omitted.

FIGS. 3A to 3C are diagrams illustrating a method for forming the base layer 5 formed of the first polyimide resin layer 1, the silicon oxide film 4, and the second polyimide resin layer 2 on a glass substrate 101.

FIG. 3A is already described in the first embodiment described above, and thus the description thereof is omitted herein.

As illustrated in FIG. 3B, the silicon oxide film 4 is formed by using CVD so as to cover at least the first polyimide resin layer 1 formed on the glass substrate 101.

In the present embodiment, the silicon oxide film 4 is provided in consideration of improvement in adhesion between the first polyimide resin layer 1 and the second polyimide resin layer 2 and improvement in moisture resistance.

The reason is that adhesion between the silicon oxide film 4 and the second polyimide resin layer 2 is higher than adhesion between the first polyimide resin layer 1 and the second polyimide resin layer 2.

In the present embodiment, the silicon oxide film 4 is used and provided to improve adhesion between the second polyimide resin layer 2 and the silicon oxide film 4 and improve moisture resistance, and thus a film thickness of the silicon oxide film 4 is not particularly limited as long as it falls within a range from which an effect of improving adhesion and an effect of improving moisture resistance are obtained. However, the silicon oxide film 4 is preferably formed to have a film thickness of about greater than or equal to 100 nm and less than or equal to 1000 nm in order to obtain a higher effect of improving moisture resistance by using the silicon oxide film 4.

An inorganic film other than the silicon oxide film 4 may be used, and, for example, a silicon nitride film may be used. These inorganic films may be formed by a method other than CVD as long as the effect of improving adhesion and the effect of improving moisture resistance can be obtained.

Note that, as illustrated in FIG. 3B, the silicon oxide film 4 is preferably provided so as to cover the entire surface of the first polyimide resin layer 1 in consideration of improvement in adhesion between the first polyimide resin layer 1 and the second polyimide resin layer 2 and improvement in moisture resistance.

As illustrated in FIG. 3C, in the second polyimide resin layer 2 formed by using a slit coater, a portion 2R (fourth portion) having a film thickness thicker than that of the other portion in the second polyimide resin layer 2 is formed near the start position of the application for the second time by the slit coater, and a portion 2L (second portion) having a film thickness thinner than that of the other portion in the second polyimide resin layer 2 is formed near the stop position of the application for the second time by the slit coater, similarly to the first polyimide resin layer 1.

As illustrated in FIGS. 3A and 3C, the first polyimide resin layer 1 and the second polyimide resin layer 2 are provided to contact each other with the silicon oxide film 4 therebetween, a portion 1L (first portion) having a film thickness thicker than that of the other portion in the first polyimide resin layer 1 overlaps the portion 2L (second portion) having a film thickness thinner than that of the other portion in the second polyimide resin layer 2 in a plan view, and a portion 1R (third portion) having a film thickness thinner than that of the other portion in the first polyimide resin layer 1 overlaps the portion 2R (fourth portion) having a film thickness thicker than that of the other portion in the second polyimide resin layer 2 in the plan view.

### Third Embodiment

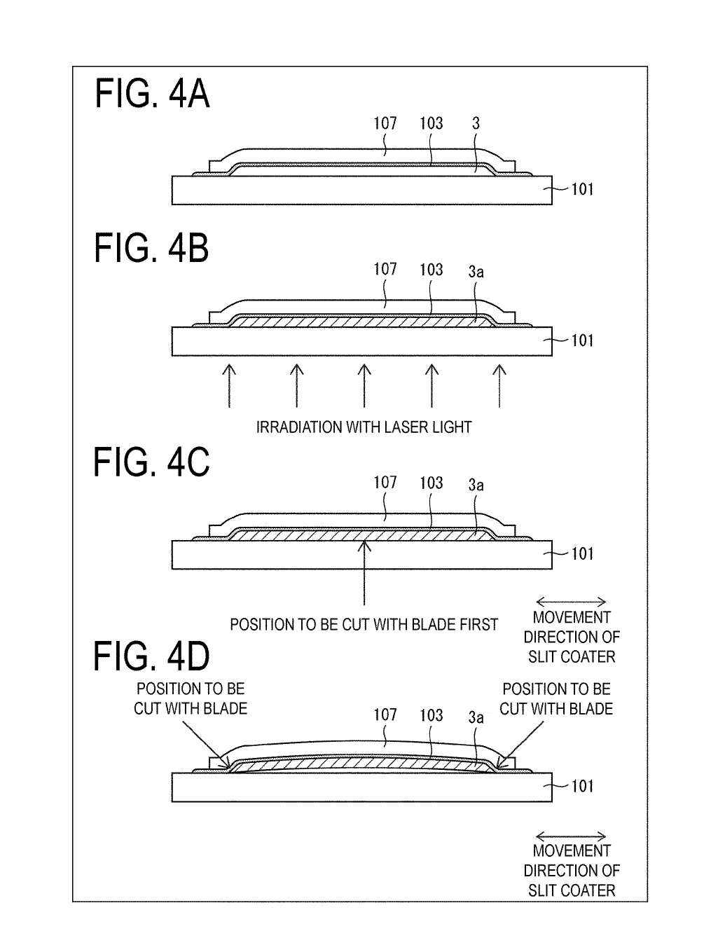

Next, a third embodiment of the disclosure will be described below with reference to FIGS. 4A to 4D. The present embodiment is different from the first and second embodiments in that, in a step of peeling a glass substrate 101 from a base layer 3a, the glass substrate 101 is first peeled from the base layer 3a at both the ends of the glass substrate 101 in a direction orthogonal to a movement direction of a slit coater, and then the glass substrate 101 is peeled from the base layer 3a at both the ends of the glass substrate 101 in the movement direction of the slit coater. The other is as described in the first and second embodiments. For convenience of descriptions, members having the same functions as those of the members illustrated in the diagrams in the first and second embodiments are denoted by the same reference numerals, and descriptions thereof will be omitted.

FIGS. 4A to 4D are diagrams illustrating the step of peeling the glass substrate 101 from the base layer 3a.

As illustrated in FIG. 4A, a base layer 3 formed of a first polyimide resin layer 1 and a second polyimide resin layer 2, a moisture-proof layer 103, and a layered body 107 are provided on the glass substrate 101.

As illustrated in FIG. 4B, irradiation with laser light from the glass substrate 101 side causes ablation at an interface between the base layer 3a and the glass substrate 101 being irradiated with laser light.

Then, as illustrated in FIG. 4C, both the ends in the direction orthogonal to the movement direction (first direction or second direction) of the slit coater are cut with a blade first, and the glass substrate 101 is partially peeled from the base layer 3a. Subsequently, as illustrated in FIG. 4D, both the ends in the movement direction (first direction or second direction) of the slit coater are cut with the blade, and the glass substrate 101 is peeled from the base layer 3a. Accordingly, the glass substrate 101 can be completely peeled from the base layer 3a.

Both the ends of the base layer 3a on the glass substrate 101 have a relatively level film thickness in the direction orthogonal to the movement direction (first direction or second direction) of the slit coater, and thus the glass substrate 101 can be more easily peeled from the base layer 3a. Thus, the peeling step can be more efficiently performed by cutting this portion with the blade first and performing peeling.

Note that, the method for cutting both the ends in the direction orthogonal to the movement direction of the slit coater with the blade first, partially peeling the glass substrate 101 from the base layer 3a, and then cutting both the ends in the movement direction of the slit coater with the blade, and peeling the glass substrate 101 from the base layer 3a is described as one example in the present embodiment, which is not limited thereto. For example, four corners of the base layer 3a on the glass substrate 101 (specifically, four corners of the first polyimide resin layer 1 on the glass substrate 101) may be cut with the blade first.

The reason why a peeling trouble can be suppressed even when the four corners of the base layer 3a of the glass substrate 101 are cut with the blade first is that a film thickness of the base layer 3 is leveled at locations corresponding to the four corners of the glass substrate 101, as described above.

A flexible display body according to the present embodiment is not particularly limited as long as it is a flexible and bendable display panel provided with an electro-optical element. The electro-optical element is an electro-optical element whose luminance and transmittance are controlled by an electric current, and examples of the electric current-controlled electro-optical element include an organic Electro Luminescence (EL) display provided with an Organic Light Emitting Diode (OLED), an EL display such as an inorganic EL display provided with an inorganic light emitting diode, or a Quantum Dot Light Emitting Diode (QLED) display provided with a QLED.

### Supplement

To solve the above-described problem, a method for manufacturing a flexible display device according to aspect 1 of the disclosure is a method for manufacturing a flexible display device including: a first step of forming a base layer on a surface on one side of a non-flexible substrate; a second step of forming a display element on the base layer; a third step of performing irradiation with laser light from a side of the non-flexible substrate and peeling the non-flexible substrate from the base layer; and a fourth step of bonding a flexible substrate to a surface of the base layer from which the non-flexible substrate is peeled. A step of forming the base layer in the first step includes a step of forming a first resin layer and a step of forming a second resin layer. The step of forming the first resin layer includes applying a first resin material while being spread in a first direction. The step of forming the second resin layer includes applying a second resin material while being spread in a second direction being a direction opposite to the first direction.

According to the above-described method, the step of forming the first resin layer includes applying the first resin material while being spread in the first direction, and the step of forming the second resin layer includes applying the second resin material while being spread in the second direction being the direction opposite to the first direction. Thus, a film thickness of the base layer is leveled by using generated variations in film thickness in each of the step of forming the first resin layer and the step of forming the second resin layer.

Therefore, setting the amount of irradiation with laser light to the base layer is easy, and a peeling trouble occurring when the non-flexible substrate is peeled from the base layer can be suppressed.

According to the above-described method, the non-flexible substrate is peeled from the base layer. Thus, a large amount of unnecessary resin layers is not left on the peeled non-flexible substrate unlike the methods described in the related art (PTLs 1 to 4 described above).

According to the above-described method, a film thickness of the base layer is leveled. Thus, a distance (gap) between a vapor deposition mask and the non-flexible substrate can be secured at a fixed distance.

According to the above-described method, the step of forming the base layer includes the step of forming the first resin layer and the step of forming the second resin layer. Thus, even when a foreign matter is mixed during the formation of the first resin layer, the second resin layer can bury this foreign matter.

Furthermore, according to the above-described method, even when each of the first resin layer and the second resin layer constituting the base layer can be formed only as a thin film, the base layer is formed of the first resin layer and the second resin layer, and can thus have a relatively thick film.

In the method for manufacturing a flexible display device of aspect 2 of the disclosure, the method being according to above-described aspect 1, the first resin material and the second resin material are preferably the same material.

According to the above-described method, a film thickness of the base layer can be leveled with a higher degree of precision.

In the method for manufacturing a flexible display device of aspect 3 of the disclosure, the method being according to above-described aspect 1 or 2, the first resin material and the second resin material may include a polyimide resin.

According to the above-described method, greater moisture resistance can be secured.

In the method for manufacturing a flexible display device of aspect 4 of the disclosure, the method being according to any of above-described aspects 1 to 3, the step of forming the first resin layer and the step of forming the second resin layer may include applying by using a slit coater.

According to the above-described method, a film thickness of the base layer can be leveled by using the slit coater.

In the method for manufacturing a flexible display device of aspect 5 of the disclosure, the method being according to any of above-described aspects 1 to 4, a step of performing heat treatment on the first resin layer may be included after the step of forming the first resin layer and before the step of forming the second resin layer.

According to the above-described method, a film thickness of the base layer can be leveled with a higher degree of precision.

In the method for manufacturing a flexible display device of aspect 6 of the disclosure, the method being according to any of above-described aspects 1 to 4, hydrophilic treatment may be performed on at least a surface of the first resin layer after the step of forming the first resin layer and before the step of forming the second resin layer.

According to the above-described method, adhesion between the first resin layer and the second resin layer can be improved.

In the method for manufacturing a flexible display device of aspect 7 of the disclosure, the method being according to above-described aspect 5, hydrophilic treatment may be performed on at least a surface of the first resin layer after the step of performing heat treatment on the first resin layer and before the step of forming the second resin layer.

According to the above-described method, adhesion between the first resin layer and the second resin layer can be improved.

In the method for manufacturing a flexible display device of aspect 8 of the disclosure, the method being according to above-described aspect 6 or 7, the hydrophilic treatment may be plasma treatment.

According to the above-described method, adhesion between the first resin layer and the second resin layer can be improved.

In the method for manufacturing a flexible display device of aspect 9 of the disclosure, the method being according to any of above-described aspects 1 to 5, a step of forming an inorganic film covering the entire surface of the first resin layer may be included after the step of forming the first resin layer and before the step of forming the second resin layer.

According to the above-described method, adhesion between the first resin layer and the second resin layer can be improved.

In the method for manufacturing a flexible display device of aspect 10 of the disclosure, the method being according to above-described aspect 9, the inorganic film may include a silicon oxide film.

According to the above-described method, adhesion between the first resin layer and the second resin layer can be improved.

In the method for manufacturing a flexible display device of aspect 11 of the disclosure, the method being according to any of above-described aspects 1 to 10, the third step may include peeling the non-flexible substrate from the base layer at both ends in a direction orthogonal to the first direction and the second direction, and then peeling the non-flexible substrate from the base layer at both ends in the first direction and the second direction.

According to the above-described method, the peeling step can be more efficiently performed.

In the method for manufacturing a flexible display device of aspect 12 of the disclosure, the method being according to above-described aspect 11, the third step may include inserting a blade into a center of a side parallel to the first direction of the first resin layer along an interface between the non-flexible substrate and the first resin layer, and peeling the non-flexible substrate from the base layer at both the ends in the direction orthogonal to the first direction and the second direction.

According to the above-described method, the peeling step can be more efficiently performed.

In the method for manufacturing a flexible display device of aspect 13 of the disclosure, the method being according to any of above-described aspects 1 to 10, the third step may include inserting a blade into four corners of the first resin layer along an interface between the non-flexible substrate and the first resin layer, and peeling the non-flexible substrate from the base layer.

According to the above-described method, the blade can be inserted into the four corners of the first resin layer along the interface between the non-flexible substrate and the first resin layer, and the non-flexible substrate can be peeled from the base layer.

In the method for manufacturing a flexible display device of aspect 14 of the disclosure, the method being according to any of above-described aspects 1 to 13, the display element may include an EL display element.

According to the configuration above, the flexible display device including the EL display element can be achieved.

In the method for manufacturing a flexible display device of aspect 15 of the disclosure, the method being according to any of above-described aspects 1 to 13, the display element may include a reflection liquid crystal display element.

According to the method above, the flexible display device including the reflection liquid crystal display element can be achieved.

To solve the above-described problem, a flexible display device according to aspect 16 of the disclosure is a flexible display device including: a flexible substrate; a base layer provided on a surface on one side of the flexible substrate; and a display element provided on the base layer. The base layer is formed of a first polyimide resin layer and a second polyimide resin layer contacting the first polyimide resin layer on the first polyimide resin layer.

According to the above-described configuration, the base layer is formed of the first polyimide resin layer and the second polyimide resin layer contacting the first polyimide resin layer on the first polyimide resin layer.

Therefore, setting the amount of irradiation with laser light to the base layer is easy, and a peeling trouble occurring when the non-flexible substrate is peeled from the base layer can be suppressed. Thus, the flexible display device having high productivity can be achieved.

To solve the above-described problem, a flexible display device according to aspect 17 of the disclosure is a flexible display device including: a flexible substrate; a base layer provided on a surface on one side of the flexible substrate; and a display element provided on the base layer. The base layer is formed of a first polyimide resin layer, an inorganic film contacting the first polyimide resin layer on the first polyimide resin layer, and a second polyimide resin layer contacting the inorganic film on the inorganic film.

According to the above-described configuration, the base layer is formed of the first polyimide resin layer, the inorganic film contacting the first polyimide resin layer on the first polyimide resin layer, and the second polyimide resin layer contacting the inorganic film on the inorganic film. Thus, setting the amount of irradiation with laser light to the base layer is easy, and a peeling trouble occurring when the non-flexible substrate is peeled from the base layer can be suppressed. Therefore, the flexible display device having high productivity can be achieved.

According to the above-described configuration, the base layer is provided with the inorganic film. Thus, the flexible display device having high moisture resistance and improved adhesion between the first polyimide resin layer and the second polyimide resin layer can be achieved.

In the flexible display device of aspect 18 of the disclosure, the flexible display device being according to above-described aspect 16 or 17, the first polyimide resin layer preferably includes a first portion having a film thickness thicker than that of the other portion, the second polyimide resin layer preferably includes a second portion having a film thickness thinner than that of the other portion, and the first portion and the second portion preferably overlap each other in a plan view.

According to the above-described configuration, a level film thickness of the base layer can be achieved.

In the flexible display device of aspect 19 of the disclosure, the flexible display device being according to any of above-described aspects 16 to 18, the first polyimide resin layer preferably includes a third portion having a film thickness thinner than that of the other portion, the second polyimide resin layer preferably includes a fourth portion having a film thickness thicker than that of the other portion, and the third portion and the fourth portion preferably overlap each other in a plan view.

According to the above-described configuration, a level film thickness of the base layer can be achieved.

In the flexible display device of aspect 20 of the disclosure, the flexible display device being according to above-described aspect 17, the first polyimide resin layer and the second polyimide resin layer may be provided inside an end portion of the inorganic film, the first polyimide resin layer may include a first portion having a film thickness thicker than that of the other portion, the second polyimide resin layer may include a second portion having a film thickness thinner than that of the other portion, and the first portion and the second portion may overlap each other in a plan view and also contact each other with the inorganic film between the first portion and the second portion.

According to the above-described configuration, the inorganic film is located between the first portion and the second portion. Thus, the flexible display device having high moisture resistance and improved adhesion between the first portion and the second portion can be achieved.

In the flexible display device of aspect 21 of the disclosure, the flexible display device being according to above-described aspect 17, the first polyimide resin layer and the second polyimide resin layer may be provided inside an end portion of the inorganic film, the first polyimide resin layer may include a third portion having a film thickness thinner than that of the other portion, the second polyimide resin layer may include a fourth portion having a film thickness thicker than that of the other portion, and the third portion and the fourth portion may overlap each other in a plan view and also contact each other with the inorganic film between the third portion and the fourth portion.

According to the above-described configuration, the inorganic film is located between the third portion and the fourth portion. Thus, the flexible display device having high moisture resistance and improved adhesion between the third portion and the fourth portion can be achieved.

In the flexible display device of aspect 22 of the disclosure, the flexible display device being according to any of above-described aspects 16 to 21, the display element may include an EL display element.

According to the configuration above, the flexible display device including the EL display element can be achieved.

In the flexible display device of aspect 23 of the disclosure, the flexible display device being according to any of above-described aspects 16 to 21, the display element may include a reflection liquid crystal display element.

According to the configuration above, the flexible display device including the reflection liquid crystal display element can be achieved.

### Additional Items

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

The disclosure is applicable to a flexible display device and a method for manufacturing a flexible display device.

### REFERENCE SIGNS LIST

1 First polyimide resin layer (first resin layer)
1L Portion having film thickness thicker than that of the other portion in first polyimide resin layer (first portion)
1R Portion having film thickness thinner than that of the other portion in first polyimide resin layer (third portion)
1a First polyimide resin layer subjected to plasma treatment
2 Second polyimide resin layer (second resin layer)
2L Portion having film thickness thinner than that of the other portion in second polyimide resin layer (second portion)
2R Portion having film thickness thicker than that of the other portion in second polyimide resin layer (fourth portion)
3 Base layer
3a Base layer irradiated with laser light
4 Silicon oxide film (inorganic film)
5 Base layer
101 Glass substrate (non-flexible substrate)
105R Red light-emitting organic EL element (display element)
105G Green light-emitting organic EL element (display element)
105B Blue light-emitting organic EL element (display element)

1-17. (canceled)

18. A flexible display device comprising:
a flexible substrate;
a base layer provided on a surface on one side of the flexible substrate; and
a display element provided on the base layer, wherein
the base layer is formed of a first polyimide resin layer and a second polyimide resin layer contacting the first polyimide resin layer on the first polyimide resin layer,
the first polyimide resin layer includes a first portion having a film thickness thicker than that of the other portion,
the second polyimide resin layer includes a second portion having a film thickness thinner than that of the other portion, and
the first portion and the second portion overlap each other in a plan view.

19. The flexible display device according to claim 18,
wherein the first polyimide resin layer includes a third portion having a film thickness thinner than that of the other portion,
the second polyimide resin layer includes a fourth portion having a film thickness thicker than that of the other portion, and
the third portion and the fourth portion overlap each other in a plan view.

20-21. (canceled)

22. The flexible display device according to claim 18,
wherein the display element is an EL display element.

23. The flexible display device according to claim 18,
wherein the display element is a reflection liquid crystal display element.

24. A flexible display device comprising:
a flexible substrate;
a base layer provided on a surface on one side of the flexible substrate; and
a display element provided on the base layer, wherein
the base layer is formed of a first polyimide resin layer and a second polyimide resin layer contacting the first polyimide resin layer on the first polyimide resin layer,
the first polyimide resin layer includes a third portion having a film thickness thinner than that of the other portion,
the second polyimide resin layer includes a fourth portion having a film thickness thicker than that of the other portion, and
the third portion and the fourth portion overlap each other in a plan view.

25. The flexible display device according to claim 24,
wherein the display element is an EL display element.

26. The flexible display device according to claim 24,
wherein the display element is a reflection liquid crystal display element.

27. A flexible display device comprising:
a flexible substrate;
a base layer provided on a surface on one side of the flexible substrate; and
a display element provided on the base layer, wherein
the base layer is formed of a first polyimide resin layer, an inorganic film contacting the first polyimide resin layer on the first polyimide resin layer, and a second polyimide resin layer contacting the inorganic film on the inorganic film,
the first polyimide resin layer includes a first portion having a film thickness thicker than that of the other portion,
the second polyimide resin layer includes a second portion having a film thickness thinner than that of the other portion, and
the first portion and the second portion overlap each other in a plan view.

28. The flexible display device according to claim 27,
wherein the first polyimide resin layer includes a third portion having a film thickness thinner than that of the other portion,
the second polyimide resin layer includes a fourth portion having a film thickness thicker than that of the other portion, and
the third portion and the fourth portion overlap each other in a plan view.

29. The flexible display device according to claim 27,
wherein the first polyimide resin layer and the second polyimide resin layer are provided inside an end portion of the inorganic film, and
the first portion and the second portion contact each other with the inorganic film between the first portion and the second portion.

30. The flexible display device according to claim 28,
wherein the first polyimide resin layer and the second polyimide resin layer are provided inside an end portion of the inorganic film, and
the third portion and the fourth portion contact each other with the inorganic film between the third portion and the fourth portion.

31. The flexible display device according to claim 27,
wherein the display element is an EL display element.

32. The flexible display device according to claim 27,
wherein the display element is a reflection liquid crystal display element.
